(19) United States
(12) Patent Application Publication
(10) Pub. No.: US 2026/0311971 A1
(43) Pub. Date: Oct. 8, 2026

(54) DEVICE FOR REDUCING A PARASITIC PLASMA AND A SUBSTRATE PROCESSING APPARATUS HAVING THE SAME

(71) Applicant: ASM IP Holding B.V., Almere (NL)

(72) Inventors: DaeYoun Kim, Seo-gu (KR); JongSu Kim, Hwaseong-si (KR)

(21) Appl. No.: 19/637,315

(22) Filed: Apr. 2, 2026

Related U.S. Application Data
(60) Provisional application No. 63/784,564, filed on Apr. 7, 2025.

(51) Int. Cl. H01J 37/32

(52) U.S. Cl. CPC H01J 37/32449; H01J 37/32467; H01J 37/32834

(57) ABSTRACT

In one embodiment of the present disclosure, a device for reducing a parasitic plasma comprises: a gas manifold; a gas channel; and an insulator located between the gas manifold and the gas channel to isolate the gas channel from the gas manifold electrically, wherein the gas manifold is metallic and grounded to reduce a parasitic plasma within the gas manifold.

### CROSS-REFERENCE TO RELATED APPLICATIONS

This application claims priority to U.S. Provisional Patent Application Ser. No. 63/784,564 filed Apr. 7, 2025 titled DEVICE FOR REDUCING A PARASITIC PLASMA AND A SUBSTRATE PROCESSING APPARATUS HAVING THE SAME, the disclosure of which is hereby incorporated by reference in its entirety.

### FIELD OF INVENTION

The present disclosure relates generally to a device for reducing a parasitic plasma and a substrate processing apparatus having the same. More particularly, the present disclosure relates to a device for reducing a parasitic plasma to be used for a gas distribution system of a substrate processing apparatus having the same.

### BACKGROUND OF THE DISCLOSURE

In a typical plasma process, a RF generator generates power at a desired RF frequency and power, and this power is transmitted through the RF cables and matching networks to the plasma chamber. A gas-phase reaction, such as chemical vapor deposition (CVD), plasma enhanced CVD (PECVD), atomic layer deposition (ALD), plasma enhanced atomic layer deposition (PEALD) and the like can be used for a variety of applications, including depositing and etching materials on a substrate surface. For example, a gas-phase reaction can be used to deposit and/or etch layers on a substrate to form semiconductor devices, flat panel display devices, photovoltaic devices, microelectromechanical systems (MEMS), and the like.

A typical substrate processing chamber for the gas-phase reaction includes a reactor, one or more precursor gas sources fluidly coupled to the reactor, one or more carrier or purge gas sources fluidly coupled to the reactor, a gas distribution system to deliver a gas or gases (e.g., a precursor gas or gases and/or a carrier or purge gas or gases) to a surface of a substrate, and an exhaust source fluidly coupled to the reactor. The substrate processing chamber also typically includes a susceptor to hold a substrate in place during processing the substrate. The susceptor can be configured to move up and down to receive a substrate and/or can rotate during processing the substrate.

In a substrate processing process using a plasma under low pressure conditions, a parasitic plasma may be formed inside the gas supply path. In the substrate processing process using a plasma, reducing the parasitic plasma within the gas supply path may be important for a film quality and a film uniformity on the substrate.

Therefore, the present disclosure presents a device for reducing a parasitic plasma and a substrate processing apparatus having the device for reducing a parasitic plasma.

### SUMMARY OF THE DISCLOSURE

This summary is provided to introduce a selection of concepts in a simplified form. These concepts are described in further detail in the detailed descriptions of exemplary embodiments of the disclosure below. This summary is not intended to identify key features or essential features of the claimed subject matter, nor is it intended to be used to limit the scope of the claimed subject matter.

In accordance with one exemplary embodiment, there may be provided a device for reducing a parasitic plasma comprising: a gas manifold; a gas channel; and an insulator located between the gas manifold and the gas channel to isolate the gas channel from the gas manifold electrically, wherein the gas manifold is metallic and grounded to reduce a parasitic plasma within the gas manifold.

In accordance with another exemplary embodiment, there may be provided a substrate processing apparatus comprising: a gas manifold; a gas channel; an insulator located between the gas manifold and the gas channel to isolate the gas channel from the gas manifold electrically; a showerhead supporting the gas channel; an exhaust duct supporting the showerhead; an outer flow control ring and an inner control ring to control a flow of an exhaust gas from a reaction space; a heater, being located facing the showerhead, to heat a substrate loaded thereon; and a power source coupled to the showerhead, wherein the gas manifold is metallic and grounded to reduce a parasitic plasma within the gas manifold, wherein the showerhead, the exhaust duct, and the heater form the reaction space.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 shows a sectional view of a prior-art substrate processing apparatus.

FIG. 2 shows a sectional view of a device for reducing a parasitic plasma and a substrate processing apparatus having the same in accordance with exemplary embodiments of the present disclosure.

FIG. 3 shows a sectional view of a gas manifold of the substrate processing apparatus in accordance with exemplary embodiments of the present disclosure.

FIG. 4 (a) shows an insulator of the substrate processing apparatus in accordance with exemplary embodiments of the present disclosure; (b) shows an enlarged top view of the insulator of the substrate processing apparatus in accordance with exemplary embodiments of the present disclosure.

FIG. 5 shows a top portion of a gas channel of the substrate processing apparatus in accordance with exemplary embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers or a liquid crystal display panel in various shapes and sizes. Substrates may be made from semiconductor materials, including, for example, silicon, silicon germanium, silicon oxide, gallium arsenide, gallium nitride and silicon carbide, or non-crystalline materials, for example, a glass substrate for liquid crystal display.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

### Substrate Processing Apparatus

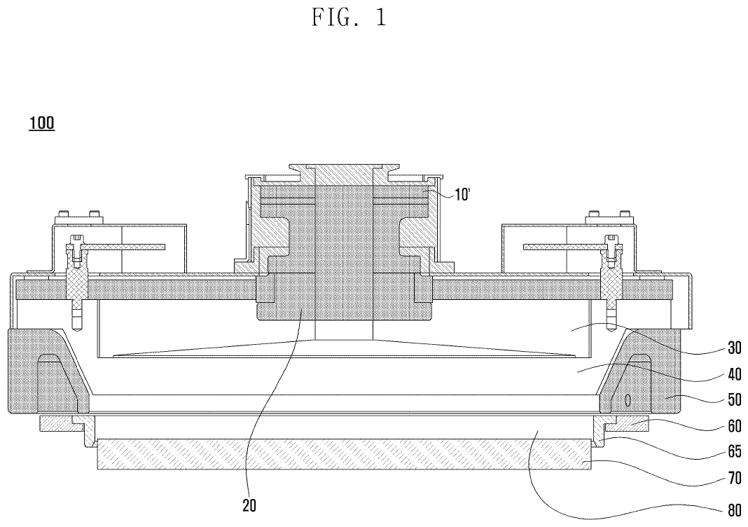

FIG. 1 shows a sectional view of a prior-art substrate processing apparatus 100. The prior-art substrate processing apparatus 100 includes an gas manifold 10′ made of a ceramic insulator; a gas channel 30; an insulator 20 located between the gas manifold 10′ and the gas channel 30; a showerhead 40 supporting the gas channel 30; an exhaust duct 50 supporting the showerhead 40; an outer flow control ring 60 and an inner flow control ring 65 to control a flow of an exhaust gas from a reaction space 80; a heater 70, being located facing the showerhead 40, to heat a substrate (not shown) loaded thereon; and a power source (not shown) coupled to the showerhead 40. The showerhead 40, the exhaust duct 50, and the heater 70 may form the reaction space 80. In a process using a high frequency power, e.g., 60 MHz, however, a parasitic plasma may occur within the gas supply path, i.e., the gas manifold 10′, resulting in undesirable film qualities, e.g., low film density, unintended film compositions, and a low film uniformity etc.

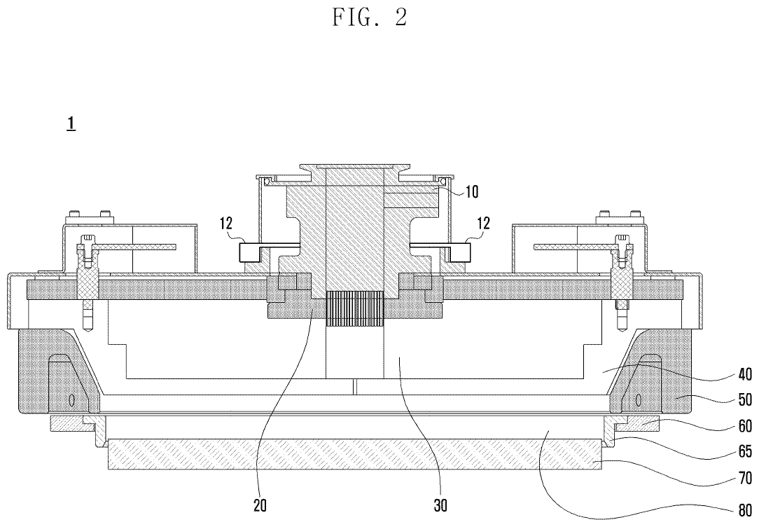

FIG. 2 shows a sectional view of a device for reducing a parasitic plasma and a substrate processing apparatus 1 having the same in accordance with exemplary embodiments of the present disclosure.

Referring to FIG. 2, a device for reducing a parasitic plasma in accordance with exemplary embodiments of the present disclosure comprises a gas manifold 10; a gas channel 30; and an insulator 20 located between the gas manifold 10 and the gas channel 30 to isolate the gas channel 30 from the gas manifold 10 electrically. The gas manifold 10 is metallic and grounded to reduce a parasitic plasma within the gas manifold 10.

Further, the substrate processing apparatus 1 in accordance with exemplary embodiments of the present disclosure comprises a gas manifold 10, a gas channel 30, and an insulator 20 located between the gas manifold 10 and the gas channel 30. The gas manifold 10 is metallic and grounded to reduce a parasitic plasma within the gas manifold 10. The gas manifold 10 comprises at least one ground connection block 12 at an outer periphery of the gas manifold 10. The insulator 20 isolates the gas channel 30 from the gas manifold 10 electrically. The substrate processing apparatus 1 further comprises an exhaust duct 50; an outer flow control ring 60; an inner flow controlling ring 65, a heater 70; and a power source (not shown). The exhaust duct 50 supports the showerhead 40. The outer and inner flow control rings 60, 65 control a flow of an exhaust gas from a reaction space 80. The heater 70 is located facing the showerhead 40 and heats a substrate (not shown) loaded on the heater 70. The power source (not shown) is coupled to the showerhead 40. The showerhead 40, the exhaust duct 50, and the heater 70 form the reaction space 80.

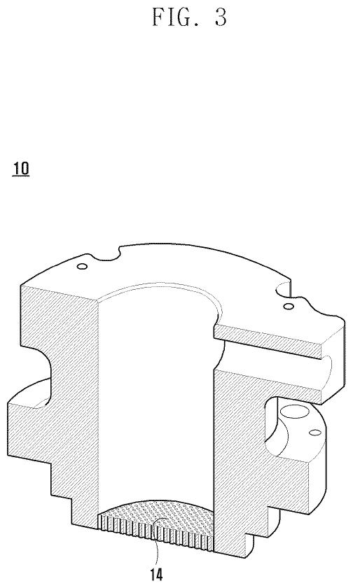

FIG. 3 shows a sectional view of the gas manifold 10 of the substrate processing apparatus 1 in accordance with exemplary embodiments of the present disclosure. The gas manifold 10 comprises a plurality of gas manifold holes 14 at a bottom portion of the gas manifold 10, wherein a pressure of an inner space of the gas manifold 10 is at least 7.5 Torr, or at least 8 Torr while supplying a gas thereto to reduce a parasitic plasma within the gas manifold 10.

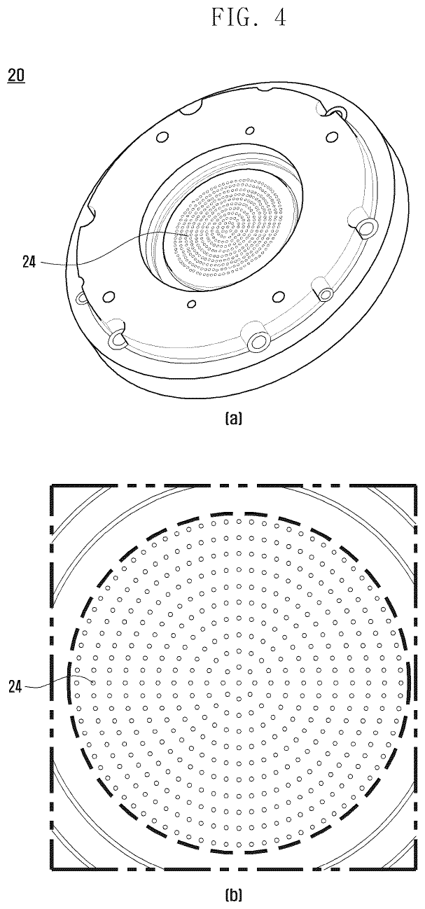

FIG. 4 (a) shows the insulator 20 of the substrate processing apparatus 1 in accordance with exemplary embodiments of the present disclosure, and FIG. 4 (b) shows an enlarged top view of the insulator 20 of the substrate processing apparatus 1 in accordance with exemplary embodiments of the present disclosure. The insulator 20 comprises a plurality of insulator holes 24, wherein each of the plurality of insulator holes 24 extends through from a bottom portion of the gas manifold 10 to a top portion of the gas channel 30. The insulator 20 comprises at least one of ceramic or celazole.

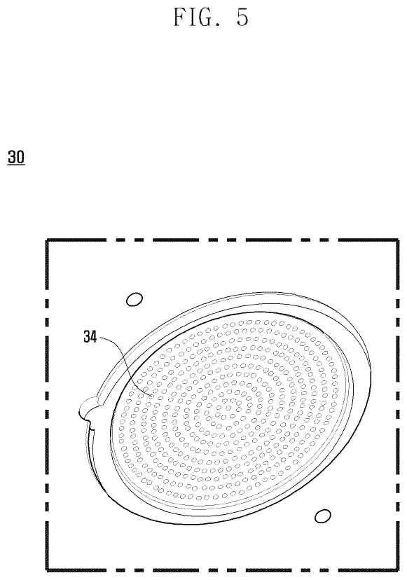

FIG. 5 shows a top portion of the gas channel 30 of the substrate processing apparatus 1 in accordance with exemplary embodiments of the present disclosure. The gas channel 30 comprises a plurality of gas channel holes 34 at a top portion of the gas channel 30 to reduce a plasma transmission from the gas manifold 10. A pattern of the plurality of gas manifold holes 14, a pattern of the plurality of insulator holes 24, and a pattern of the plurality of gas channel holes 34 are aligned such that a gas can flow through the plurality of holes of gas manifold holes 14, the plurality of insulator holes 24, and the plurality of gas channel holes 34 without any gas leakage.

Referring to FIGS. 3 to 5, in a substrate processing process at low pressure conditions in the substrate processing apparatus 1, a parasitic plasma may be generated inside the gas manifold 10. The gas manifold 10 may be formed of metal and be grounded to reduce the parasitic plasma within the gas manifold 10. The gas channel 30 comprises the plurality of gas channel holes 34 at a top portion of the gas channel 30 to reduce a plasma transmission from the manifold 10.

The gas manifold holes 14 formed at the bottom of the gas manifold 10 may lower a gas conductance of an inner space of the gas manifold 10 while supplying a gas thereto, resulting in a pressure increase therein. Therefore, a parasitic plasma may be reduced within the gas manifold 10. In some embodiments, the pressure in the inner space of the gas manifold 10 may be at least 7.5 Torr, or more preferably at least 8 Torr while supplying a gas thereto.

The insulator holes 24 formed in the insulator 20 and the gas channel holes 34 formed in the gas channel 30 may reduce a plasma transmission from the gas manifold 10 to the inner space surrounded by the insulator 20 and the gas channel 30.

While the present invention has been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

The above-described arrangements of a device for reducing a parasitic plasma and a substrate processing apparatus having the same in a substrate process are merely illustrative of applications of the principles of this invention and many other embodiments and modifications may be made without departing from the spirit and scope of the invention as defined in the claims. The scope of the present invention should, therefore, be determined not with reference to the above description, but instead should be determined with reference to the appended claims along with their full scope of equivalents.

1. A device for reducing a parasitic plasma comprising:
a gas manifold;
a gas channel; and
an insulator located between the gas manifold and the gas channel to isolate the gas channel from the gas manifold electrically,
wherein the gas manifold is metallic and grounded to reduce a parasitic plasma within the gas manifold.

2. The device for reducing a parasitic plasma of claim 1, wherein the gas manifold comprises at least one ground connection block at an outer periphery of the gas manifold.

3. The device for reducing a parasitic plasma of claim 1, wherein the gas manifold comprises a plurality of gas manifold holes at a bottom portion of the gas manifold, wherein a pressure of an inner space of the gas manifold is at least 7.5 Torr, or at least 8 Torr while supplying a gas thereto to reduce a parasitic plasma within the gas manifold.

4. The device for reducing a parasitic plasma of claim 1, wherein the insulator comprises a plurality of insulator holes, wherein each of the plurality of insulator holes extends through from a bottom portion of the gas manifold to a top portion of the gas channel.

5. The device for reducing a parasitic plasma of claim 1, wherein the gas channel comprises a plurality of gas channel holes at a top portion of the gas channel to reduce a plasma transmission from the gas manifold.

6. The device for reducing a parasitic plasma of any one of claims 3 to 5, wherein a pattern of the plurality of gas manifold holes, a pattern of the plurality of insulator holes, and a pattern of the plurality of gas channel holes are aligned such that a gas can flow through the plurality of gas manifold holes, the plurality of insulator holes, and the plurality of gas channel holes without any gas leakage.

7. The device for reducing a parasitic plasma of claim 1, wherein the insulator is formed of at least one of ceramic and celazole.

8. A substrate processing apparatus comprising:
a gas manifold;
a gas channel;
an insulator located between the gas manifold and the gas channel to isolate the gas channel from the gas manifold electrically;
a showerhead supporting the gas channel;
an exhaust duct supporting the showerhead;
an outer flow control ring and an inner control ring to control a flow of an exhaust gas from a reaction space;
a heater, being located facing the showerhead, to heat a substrate loaded thereon; and
a power source coupled to the showerhead,
wherein the gas manifold is metallic and grounded to reduce a parasitic plasma within the gas manifold, and
wherein the showerhead, the exhaust duct, and the heater define the reaction space.

9. The substrate processing apparatus of claim 8, wherein the gas manifold comprises a ground connection block at an outer periphery of the gas manifold.

10. The substrate processing apparatus of claim 8, wherein the gas manifold comprises a plurality of gas manifold holes at a bottom portion of the gas manifold, wherein a pressure of an inner space of the gas manifold is at least 7.5 Torr, or at least 8 Torr while supplying a gas thereto to reduce a parasitic plasma within the gas manifold.

11. The substrate processing apparatus of claim 8, wherein the insulator comprises a plurality of insulator holes, wherein each of the plurality of insulator holes extends through from a bottom portion of the gas manifold to a top portion of the gas channel.

12. The substrate processing apparatus of claim 8, wherein the gas channel comprises a plurality of gas channel holes at a top portion of the gas channel to reduce a plasma transmission from the gas manifold to an inner space surrounded by the insulator and the gas channel.

13. The substrate processing apparatus of any one of claims 10 to 12, wherein a pattern of the plurality of gas manifold holes, a pattern of the plurality of insulator holes, and a pattern of the plurality of gas channel holes are aligned such that a gas can flow through the plurality of gas manifold holes, the plurality of insulator holes, and the plurality of gas channel holes without any gas leakage.

14. The substrate processing apparatus of 8, wherein the insulator comprises at least one of ceramic or celazole.
